(19) United States
(12) Patent Application Publication
(10) Pub. No.: US 2026/0196940 A1
(43) Pub. Date: Jul. 9, 2026

(54) Supercapacitor-Integrated Power Conversion System

(71) Applicant: AA Power Inc., Boston, MA (US)

(72) Inventor: Qun Lu, Lexington, MA (US)

(21) Appl. No.: 19/439,444

(22) Filed: Jan. 4, 2026

Related U.S. Application Data
(60) Provisional application No. 63/741,928, filed on Jan. 5, 2025.

(51) Int. Cl. H02M 3/335; H02M 1/42

(52) U.S. Cl. CPC H02M 3/33576; H02M 1/4291

(57) ABSTRACT

A power conversion system includes a plurality of power factor correction converters connected between an ac power source and an intermediate voltage bus, a plurality of capacitors coupled to the intermediate voltage bus, wherein the plurality of capacitors is configured as holdup capacitors and a temperature of the plurality of capacitors is controlled by a liquid cooling system, and a plurality of power converters connected between the intermediate voltage bus and an output voltage bus.

### PRIORITY

This application claims the benefit of U.S. Provisional Application No. 63/741,928, filed on Jan. 5, 2025, entitled “Supercapacitor-Integrated Power Conversion System,” which application is hereby incorporated herein by reference.

### TECHNICAL FIELD

The present disclosure relates to energy storage and power conversion systems, and more particularly, to the integration of supercapacitors in power supplies to enhance energy delivery reliability and performance.

### BACKGROUND

Modern power conversion systems are indispensable across a variety of critical applications, including industrial operations, remote installations, and especially data centers. These systems frequently encounter challenges in maintaining stable energy delivery, particularly during power interruptions or voltage fluctuations. Conventional solutions rely heavily on electrolytic capacitors to provide hold-up time and stabilize voltage fluctuations. However, these capacitors face inherent limitations that severely impact their efficiency and reliability.

Electrolytic capacitors, while widely used, are inherently large in size and occupy significant space within power systems. This spatial demand becomes even more pronounced in high-power applications where numerous capacitors must be used in parallel to achieve the required energy storage capacity. Furthermore, these components are subject to aging and degradation, especially under thermal and electrical stress, leading to frequent maintenance requirements and reduced operational lifespan.

To address these challenges, advancements in energy storage technology have identified supercapacitors as a viable alternative. Supercapacitors offer several advantages over traditional electrolytic capacitors, including significantly higher energy density, superior charge and discharge rates, and a longer cycle life. These attributes make them particularly well-suited for applications requiring rapid energy delivery and consistent performance. In the present disclosure, the integration of supercapacitors into power conversion systems is further enhanced by thermal management solutions, including liquid cooling, to enable their effective operation despite the generation of heat by the supercapacitor. The disclosure provides tailored solutions for leveraging the unique properties of supercapacitors, offering improvements in reliability, efficiency, and system size, particularly in data center environments where power stability is critical. The present disclosure offers advancements to meet these challenges.

### SUMMARY

These and other problems are generally solved or circumvented, and technical advantages are generally achieved, by preferred embodiments of the present disclosure which provide a supercapacitor-integrated power conversion apparatus and method for reliable and high-performance energy delivery.

In accordance with an embodiment, a power conversion system comprises a plurality of power factor correction converters connected between an ac power source and an intermediate voltage bus, a plurality of capacitors coupled to the intermediate voltage bus, wherein the plurality of capacitors is configured as holdup capacitors and a temperature of the plurality of capacitors is controlled by a liquid cooling system, and a plurality of power converters connected between the intermediate voltage bus and an output voltage bus.

In accordance with another embodiment, a method comprises providing a power conversion system comprises a plurality of power factor correction converters connected between an ac power source and an intermediate voltage bus, a plurality of capacitors coupled to the intermediate voltage bus, and a plurality of power converters connected between the intermediate voltage bus and an output voltage bus, and configuring a liquid cooling system to control a temperature of the plurality of capacitors below a predetermined temperature threshold.

In accordance with yet another embodiment, a system comprises a plurality of power factor correction converters connected between an ac power source and an intermediate voltage bus, a plurality of power converters connected between the intermediate voltage bus and an output voltage bus, and a plurality of electrolytic capacitors and a plurality of supercapacitors coupled to at least one of respective inputs of the plurality of power factor correction converters, the intermediate voltage bus and the output voltage bus, wherein the plurality of electrolytic capacitors and the plurality of supercapacitors form a hybrid energy charge/discharge apparatus configured to buffer power variations in the system.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a block diagram of a first implementation of a power conversion system in accordance with various embodiments of the present disclosure;

FIG. 2 illustrates a schematic diagram of a first implementation of the first power factor correction converter shown in FIG. 1 in accordance with various embodiments of the present disclosure;

FIG. 3 illustrates a schematic diagram of the first power converter shown in FIG. 1 in accordance with various embodiments of the present disclosure;

FIG. 4 illustrates a schematic diagram of a second implementation of the first power factor correction converter shown in FIG. 1 in accordance with various embodiments of the present disclosure;

FIG. 5 illustrates a schematic diagram of a third implementation of the first power factor correction converter shown in FIG. 1 in accordance with various embodiments of the present disclosure;

FIG. 6 illustrates a schematic diagram of a first implementation of the supercapacitor-based energy storage apparatus shown in FIG. 1 in accordance with various embodiments of the present disclosure;

FIG. 7 illustrates a block diagram of a second implementation of the supercapacitor-based energy storage apparatus shown in FIG. 1 in accordance with various embodiments of the present disclosure;

FIG. 8 illustrates a block diagram of a third implementation of the supercapacitor-based energy storage apparatus shown in FIG. 1 in accordance with various embodiments of the present disclosure;

FIG. 9 illustrates a block diagram of a second implementation of a power conversion system in accordance with various embodiments of the present disclosure;

FIG. 10 illustrates a block diagram of a first implementation of the system shown in FIG. 9 in accordance with various embodiments of the present disclosure;

FIG. 11 illustrates a block diagram of a second implementation of the system shown in FIG. 9 in accordance with various embodiments of the present disclosure;

FIG. 12 illustrates a block diagram of a third implementation of the system shown in FIG. 9 in accordance with various embodiments of the present disclosure;

FIG. 13 illustrates a block diagram of a third implementation of a power conversion system in accordance with various embodiments of the present disclosure;

FIG. 14 illustrates a block diagram of a first implementation of the system shown in FIG. 13 in accordance with various embodiments of the present disclosure;

FIG. 15 illustrates a block diagram of a second implementation of the system shown in FIG. 13 in accordance with various embodiments of the present disclosure;

FIG. 16 illustrates a block diagram of a fourth implementation of a power conversion system in accordance with various embodiments of the present disclosure;

FIG. 17 illustrates a block diagram of a fifth implementation of a power conversion system in accordance with various embodiments of the present disclosure;

FIG. 18 illustrates a block diagram of a sixth implementation of a power conversion system in accordance with various embodiments of the present disclosure;

FIG. 19 illustrates a block diagram of a seventh implementation of a power conversion system in accordance with various embodiments of the present disclosure;

FIG. 20 illustrates a block diagram of an eighth implementation of a power conversion system in accordance with various embodiments of the present disclosure;

FIG. 21 illustrates a block diagram of a first implementation of the system shown in FIG. 20 in accordance with various embodiments of the present disclosure;

FIG. 22 illustrates a block diagram of a second implementation of the system shown in FIG. 20 in accordance with various embodiments of the present disclosure;

FIG. 23 illustrates a block diagram of a ninth implementation of a power conversion system in accordance with various embodiments of the present disclosure;

FIG. 24 illustrates a block diagram of a tenth implementation of a power conversion system in accordance with various embodiments of the present disclosure; and

FIG. 25 illustrates a flow chart of a method for configuring the power conversion system shown in FIG. 1 in accordance with various embodiments of the present disclosure.

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Further, one or more features from one or more of the following described embodiments may be combined to create alternative embodiments not explicitly described, and features suitable for such combinations are understood to be within the scope of this disclosure. It is therefore intended that the appended claims encompass any such modifications or embodiments.

The present disclosure will be described with respect to preferred embodiments in a specific context, namely a power conversion system incorporating supercapacitors, and more particularly, a power conversion system to enhance energy delivery reliability and performance. The disclosure may also be applied, however, to a variety of power conversion systems. Hereinafter, various embodiments will be explained in detail with reference to the accompanying drawings.

In power conversion systems, hold-up time is the duration for which a power supply maintains a stable DC output voltage after the loss of AC input. This capability is crucial for ensuring uninterrupted operation of electronic systems during transient power outages or voltage fluctuations. Traditional approaches to extending hold-up time involve connecting large electrolytic capacitors in parallel to the intermediate voltage bus. While effective, this approach introduces challenges, including increased system size, cost, and reliability issues. Large-capacity electrolytic capacitors are bulky, often occupying a significant portion of the power supply volume, especially in high-power applications. Additionally, differences in capacitor characteristics, such as internal resistance, lead to uneven current distribution in parallel configurations, increasing the risk of damage and requiring additional circuitry for current sharing. Furthermore, electrolytic capacitors degrade over time, reducing system reliability and necessitating frequent replacements.

To overcome these limitations, the present disclosure integrates supercapacitors into the power conversion system to address hold-up time challenges. Supercapacitors offer significantly higher energy density than electrolytic capacitors, allowing for a more compact design. Their rapid charge and discharge capabilities, combined with superior thermal stability and slower aging, provide a reliable and efficient alternative for energy storage. In the disclosed system, supercapacitors are integrated into the intermediate voltage bus, either directly or through a dedicated power converter. During normal operation, the voltage on the intermediate voltage bus charges the supercapacitors. In the event of an AC power loss, the supercapacitors discharge stored energy to maintain the required hold-up time, ensuring uninterrupted operation of the connected load. Furthermore, the supercapacitors form an energy storage device configured to be used for transient buffering.

The present disclosure reduces the reliance on large electrolytic capacitors, addressing the challenges of size, cost, and reliability. By replacing or supplementing electrolytic capacitors with supercapacitors, the system achieves a smaller overall design, suitable for space-constrained applications, enhanced durability due to the longer lifespan and reduced degradation of supercapacitors, and reduced need for additional current-sharing circuitry and lower thermal management costs.

In addition to extending hold-up time, modern high-performance computing systems such as those employing artificial-intelligence (AI) processors and accelerators present significant challenges due to rapid and frequent load transients. AI chips often transition abruptly between inactive states and high-power operating states. When an AI processor becomes inactive, its instantaneous power consumption may drop sharply, causing excess energy to be delivered from the front-end power source. Conversely, when the AI processor resumes operation, its power demand can increase rapidly, resulting in a transient power deficit. Such abrupt power variations can induce voltage fluctuations on the intermediate voltage bus, degrade power quality, and stress upstream power conversion stages.

In various embodiments of the present disclosure, the energy storage devices, including electrolytic capacitors and supercapacitors, are further configured to buffer energy during these load transients. When the load power suddenly decreases, the energy storage devices absorb excess energy from the intermediate voltage bus, thereby suppressing voltage overshoot and preventing power surges from propagating to the input side. When the load power rapidly increases, the stored energy is released to supplement the power delivered by the power factor correction converters and downstream power converters, mitigating voltage droop and improving transient response. By dynamically absorbing and releasing energy in response to load variations, the disclosed system stabilizes the intermediate voltage bus, reduces stress on power conversion components, and enhances overall system efficiency and reliability in AI and other high-dynamic-load applications.

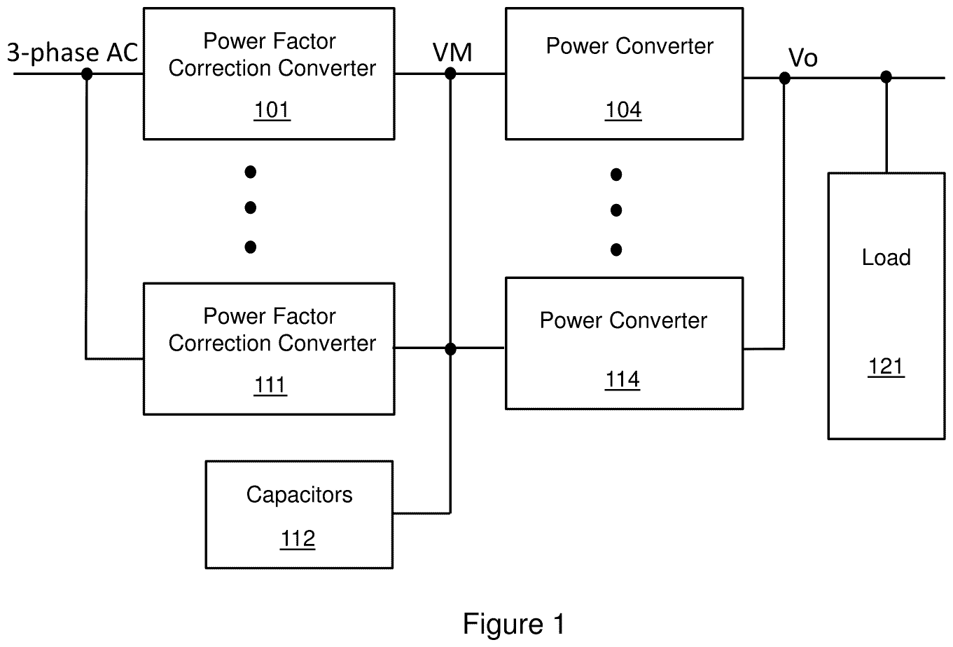

FIGS. 1-25 of the present disclosure illustrate a power conversion system incorporating supercapacitors. As shown in FIG. 1, the system includes an ac power source connected to a plurality of PFC converters (e.g., power factor converters 101 and 111), which in turn is coupled to an intermediate voltage bus VM. The intermediate voltage bus VM supplies energy to a plurality of power converters (e.g., power converters 104 and 114) and ultimately to a load 121. Supercapacitors are connected to the intermediate voltage bus VM to store energy and discharge during ac power interruptions. The design of the power conversion system allows for flexibility in integrating supercapacitors, whether directly connected to the intermediate voltage bus VM or through a converter interface. This flexibility ensures optimal performance across various operating conditions and simplifies system adaptation to different application requirements.

FIG. 1 illustrates a block diagram of a first implementation of a power conversion system in accordance with various embodiments of the present disclosure. As shown in FIG. 1, a first power factor correction converter 101 is coupled between the ac source and the intermediate voltage bus VM. A second power factor correction converter 111 is coupled between the ac source and the intermediate voltage bus VM. A plurality of capacitors 112 is hold-up capacitors coupled to VM.

In accordance with an embodiment of the present invention, the plurality of capacitors 112 includes at least one of the following implementations: a plurality of supercapacitors, a combination of supercapacitors and electrolytic capacitors, or a combination of supercapacitors, electrolytic capacitors, and batteries. The integration of these components enhances the system's energy storage capacity and flexibility, catering to varying operational requirements. Throughout the description, the plurality of capacitors 112 may be alternatively referred to as a supercapacitor-based energy storage apparatus.

In some embodiments, the plurality of supercapacitors and the plurality of electrolytic capacitors form an energy pack assembly. The energy pack assembly is integrated either within a single Power Supply Unit (PSU) or a power shelf to optimize space utilization and system integration.

In some embodiments, the power conversion system shown in FIG. 1 incorporates a liquid cooling system configured to regulate the temperature of the capacitors below a predetermined threshold, such as 35 degrees Celsius. This cooling mechanism ensures that the supercapacitors and/or batteries, if present, operate within an optimal thermal range, thereby maximizing their performance and longevity.

The liquid cooling system is designed to target specific components, such as the supercapacitors and/or batteries, but can also extend to encompass the entire power conversion system. This comprehensive cooling configuration achieves a uniform thermal profile, enhancing the overall reliability and efficiency of the system.

By integrating the liquid cooling system, the present disclosure enables the supercapacitors to sustain high energy densities and rapid charge/discharge cycles without thermal degradation. The cooling system's adaptability to either targeted or system-wide applications further supports the scalability and operational stability of the power conversion system, particularly in environments requiring consistent energy delivery.

In some embodiments, the liquid cooling system is implemented within a sealed housing or sealed enclosure that defines a coolant containment volume. The sealed housing is configured to prevent leakage of coolant to external components and to isolate the cooled components from ambient air and contaminants such as dust and moisture.

In some embodiments, the sealed housing is configured to cool at least the plurality of capacitors (e.g., supercapacitors and/or electrolytic capacitors). For example, the capacitors may be mounted to, or thermally coupled with, one or more cold plates located inside the sealed housing. Coolant flowing through internal channels of the cold plate absorbs heat generated by the capacitors, thereby maintaining a temperature of the capacitors below the predetermined temperature threshold.

In some embodiments, the sealed housing provides system-level liquid cooling for multiple power-stage components. For example, the sealed housing may contain one or more cold plates or liquid-cooled heat spreaders that are thermally coupled to the plurality of power factor correction converters, the plurality of capacitors, and the plurality of power converters. In this configuration, coolant circulated within the sealed housing removes heat from the power factor correction converters, the capacitors, and the power converters to provide a uniform thermal environment and improved reliability.

The sealed housing may be integrated within a power supply unit, a power shelf, or another power electronics enclosure. In some embodiments, coolant is circulated through the sealed housing in a closed-loop arrangement including a pump and a heat exchanger located outside the sealed housing.

As shown in FIG. 1, a first power converter 104 is connected between the intermediate voltage bus VM and the output voltage bus Vo. A second power converter 114 is connected between the intermediate voltage bus VM and the output voltage bus Vo.

It should be recognized that while FIG. 1 illustrates the power conversion system with two power factor correction converters and two power converters, the power conversion system could accommodate any number of power factor correction converters and power converters.

In some embodiments, the ac source is a three-phase ac source comprising a first phase, a second phase and a third phase. For each power delivery branch, the intermediate voltage bus VM is between the power factor correction converters and the power converters. A voltage on this voltage bus (VM) is in a range from about 360 V to about 400 V.

In a conventional power conversion system, the power factor correction converter is coupled to a single-phase ac source. Balancing the phases of the ac input becomes necessary. In other words, when a single-phase ac source is used, there is a necessity to balance three-phase power to minimize power loss on the neutral line. In contrast, a three-phase power factor correction converter produces significantly less harmonic distortion than a single-phase power factor correction converter. Lower harmonic distortion leads to better power quality and tight output voltage regulation. The tight regulation of the three-phase power factor correction converter allows an unregulated power converter coupled between the intermediate voltage bus VM and the load. In some embodiments, the unregulated power converter operating at a fixed duty cycle (e.g., a 50% duty cycle) may offer the highest efficiency because it minimizes switching losses and reduces conduction losses in the power components. At 50% duty cycle, the converter operates symmetrically, which leads to balanced energy transfer between the input and output, reducing the stress on components like transistors and magnetic components (e.g., transformers and inductors). This balance allows the converter to operate at its optimal point, minimizing energy waste in the form of heat and maximizing the efficiency of power transfer.

In some embodiments, the load 121 is a plurality of crypto miners in a crypto farm. Each crypto miner may comprise a plurality of graphics processing units (GPUs), a plurality of application-specific integrated chips (ASICs), any combinations thereof and the like.

In some embodiments, the power factor correction converter (e.g., the first power factor correction converter 101) is a three-phase buck-type power factor correction rectifier. The three-phase buck-type power factor correction rectifier is configured to convert the three-phase ac source into a dc voltage in a range from about 360 V to about 400 V. In alternative embodiments, depending on different applications and design needs, the power factor correction converter may be implemented as a Vienna rectifier or a Swiss rectifier. Furthermore, the power factor correction converter may be a non-isolated power converter (e.g., a boost converter) or an isolated power converter with a forward topology, a fly-forward topology, a flyback topology, any combinations thereof and the like.

In some embodiments, the power converter (e.g., first power converter 104) is an inductor-inductor-capacitor (LLC) resonant converter. The LLC resonant converter offers two power conversion approaches. In a first approach, the LLC resonant converter directly converts the voltage on the high voltage bus VM (e.g., 380 V) to a lower voltage (e.g., 20 V). In a second approach, the LLC resonant converter directly converts the voltage on the high voltage bus VM (e.g., 380 V) to a lower bus voltage (e.g., 48 V or 12 V), and subsequently distributes power to GPUs or ASICs via point-of-load dc/dc power converters.

In alternative embodiments, depending on different applications and design needs, the power converter may be implemented as an isolated power converter such as a forward converter, a flying converter, a fly-forward converter, a full bridge converter, a half bridge converter, any combinations thereof and the like.

In operation, the three-phase buck-type power factor correction rectifier is controlled such that the LLC resonant converter is configured to operate at a predetermined duty cycle (e.g., 50%). Alternatively, the three-phase buck-type power factor correction rectifier is controlled such that the LLC resonant converter is configured to operate at a predetermined switching frequency.

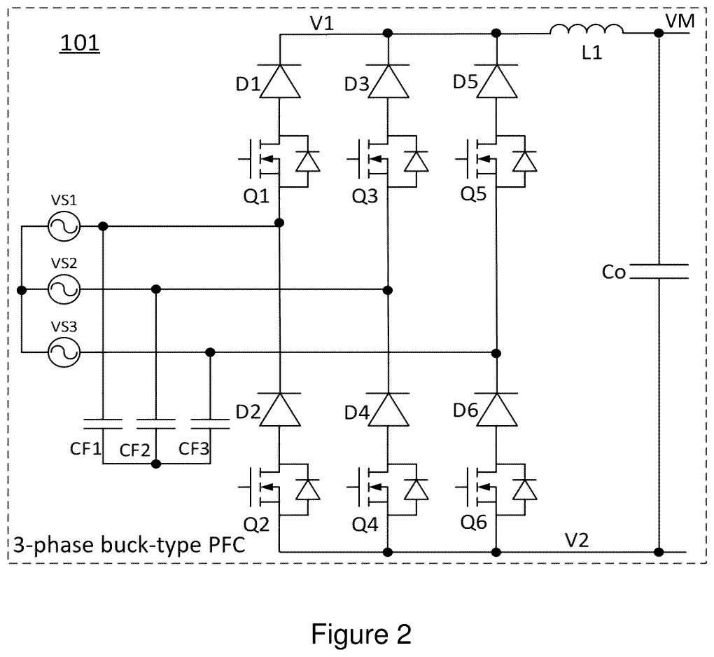

FIG. 2 illustrates a schematic diagram of a first implementation of the first power factor correction converter shown in FIG. 1 in accordance with various embodiments of the present disclosure. The first power factor correction converter is implemented as a three-phase buck-type power factor correction rectifier. As shown in FIG. 2, the three-phase buck-type power factor correction rectifier comprises three filter capacitors CF1, CF2 and CF3, three switch legs, an inductor L1 and an output capacitor Co.

As shown in FIG. 2, a first filter capacitor CF1 is connected between an output of a first phase VS1 of the three-phase ac source and a neutral point. A second filter capacitor CF2 is connected between an output of a second phase VS2 of the three-phase ac source and the neutral point. A third filter capacitor CF3 is connected between an output of a third phase VS3 of the three-phase ac source and the neutral point.

A first leg comprises a first diode D1, a first power switch Q1, a second diode D2 and a second power switch Q2. The first diode D1, the first power switch Q1, the second diode D2 and the second power switch Q2 are connected in series between a first voltage bus V1 and a second voltage bus V2. A common node of the first power switch Q1 and the second diode D2 is connected to the first phase VS1 of the three-phase ac source as shown in FIG. 2.

A second leg comprises a third diode D3, a third power switch Q3, a fourth diode D4 and a fourth power switch Q4. The third diode D3, the third power switch Q3, the fourth diode D4 and the fourth power switch Q4 are connected in series between the first voltage bus V1 and the second voltage bus V2. A common node of the third power switch Q3 and the fourth diode D4 is connected to the second phase VS2 of the three-phase ac source as shown in FIG. 2.

A third leg comprises a fifth diode D5, a fifth power switch Q5, a sixth diode D6 and a sixth power switch Q6. The fifth diode D5, the fifth power switch Q5, the sixth diode D6 and the sixth power switch Q6 are connected in series between the first voltage bus V1 and the second voltage bus V2. A common node of the fifth power switch Q5 and the sixth diode D6 is connected to the third phase VS3 of the three-phase ac source as shown in FIG. 2.

The inductor L1 is connected between the first voltage bus V1 and the high voltage bus VM. The output capacitor Co is connected between the high voltage bus VM and the second voltage bus V2. In some embodiments, the output capacitor Co comprises an electrolytic capacitor. In alternative embodiments, the output capacitor Co comprises a plurality of electrolytic capacitors connected in parallel.

In operation, the three-phase buck-type power factor correction rectifier selectively controls the power switches Q1, Q2, Q3, Q4, Q5 and Q6 to shape input currents drawn from the three-phase ac source such that the input currents are substantially in phase with corresponding phase voltages. For each ac phase, one of the upper power switches (Q1, Q3 and Q5) or one of the lower power switches (Q2, Q4 and Q6) is switched in coordination with the respective diodes to conduct current during appropriate portions of the ac line cycle. Energy from the three-phase ac source is transferred to the first voltage bus V1 and then delivered through the inductor L1 to the high voltage bus VM. The inductor L1 operates to regulate the current flowing into the high voltage bus VM, thereby enabling buck-type conversion and smoothing the pulsating input power. The output capacitor Co filters the voltage on the high voltage bus VM to provide a substantially regulated dc output voltage while reducing voltage ripple.

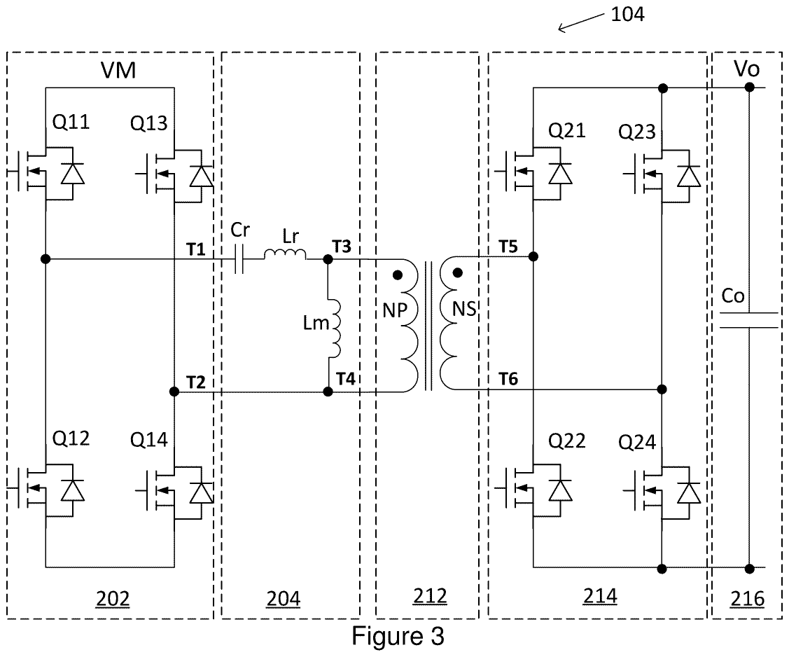

FIG. 3 illustrates a schematic diagram of the first power converter shown in FIG. 1 in accordance with various embodiments of the present disclosure. The power converter (e.g., 104) is implemented as an LLC resonant converter. As shown in FIG. 3, the LLC resonant converter comprises a switch network 202, a resonant tank 204, a transformer 212, a rectifier 214 and an output filter 216. As shown in FIG. 3, the switch network 202, the resonant tank 204, the transformer 212, the rectifier 214 and the output filter 216 are coupled to each other and connected in cascade between the input voltage bus VM and the output voltage bus Vo.

The switch network 202 includes four switching elements, namely Q11, Q12, Q13 and Q14. Throughout the description, the switch network 202 is alternatively referred to as a primary switch network.

As shown in FIG. 3, a first pair of switching elements Q11 and Q12 are connected in series between the input voltage bus VM and a primary ground. A second pair of switching elements Q13 and Q14 are connected in series between the input voltage bus VM and the primary ground. The common node of the switching elements Q11 and Q12 is coupled to a first input terminal T1 of the resonant tank 204. Likewise, the common node of the switching elements Q13 and Q14 is coupled to a second input terminal T2 of the resonant tank 204.

FIG. 3 further illustrates the resonant tank 204 is coupled between the switch network 202 and the transformer 212. The resonant tank 204 is formed by a series resonant inductor Lr, a series resonant capacitor Cr and a parallel inductance Lm. As shown in FIG. 3, the series resonant inductor Lr and the series resonant capacitor Cr are connected in series and further coupled to the primary side of the transformer 212.

It should be noted while FIG. 3 shows the series resonant inductor Lr is an independent component, the series resonant inductor Lr may be replaced by the leakage inductance of the transformer 212. In other words, the leakage inductance (not shown) may function as the series resonant inductor Lr.

It should further be noted while FIG. 3 shows the resonant tank is placed on the primary side of the LLC resonant converter, this diagram is merely an example. A person skilled in the art will recognize many variations, alternatives and modifications. For example, the resonant tank may be placed on the secondary side. Furthermore, the resonant tank may be placed on both sides of the transformer 212.

The transformer 212 has a primary winding NP and a secondary winding NS. The primary winding is coupled to terminals T3 and T4 of the resonant tank 204 as shown in FIG. 3. The secondary winding is coupled to the output of the LLC resonant converter through the rectifier 214, which is a full-bridge rectifier comprising switches Q21, Q22, Q23 and Q24. Throughout the description, the rectifier 214 is alternatively referred to as a secondary switch network.

As shown in FIG. 3, switches Q21 and Q22 are connected in series and further coupled between two terminals of the output capacitor Co. Switches Q23 and Q24 are connected in series and further coupled between the two terminals of the output capacitor Co. The common node T5 of the switches Q21 and Q22 is coupled to a first terminal of the secondary winding of the transformer 212. Likewise, the common node T6 of the switches Q23 and Q24 is coupled to a second terminal of the secondary winding of the transformer 212.

It should be noted that the transformer structure shown in FIG. 3 is merely an example. One person skilled in the art will recognize many alternatives, variations and modification. For example, the secondary side of the transformer 212 may be a center tapped transformer winding. As a result, the secondary side may employ a synchronous rectifier formed by two switching elements. The operation principle of a synchronous rectifier coupled to a center tapped transformer winding is well known, and hence is not discussed in further detail herein to avoid repetition.

It should further be noted that the power topology of the LLC resonant converter may be not only applied to the rectifier as shown in FIG. 3, but also applied to other secondary configurations, such as voltage doubler rectifiers, current doubler rectifiers, any combinations thereof and/or the like.

In operation, when the switching frequency of the LLC resonant converter is equal to the resonant frequency of the resonant tank of the LLC resonant converter, the LLC resonant converter may have a unity system gain. On the other hand, when the switching frequency of the LLC resonant converter is higher than the resonant frequency, the LLC resonant converter is of a lower system gain.

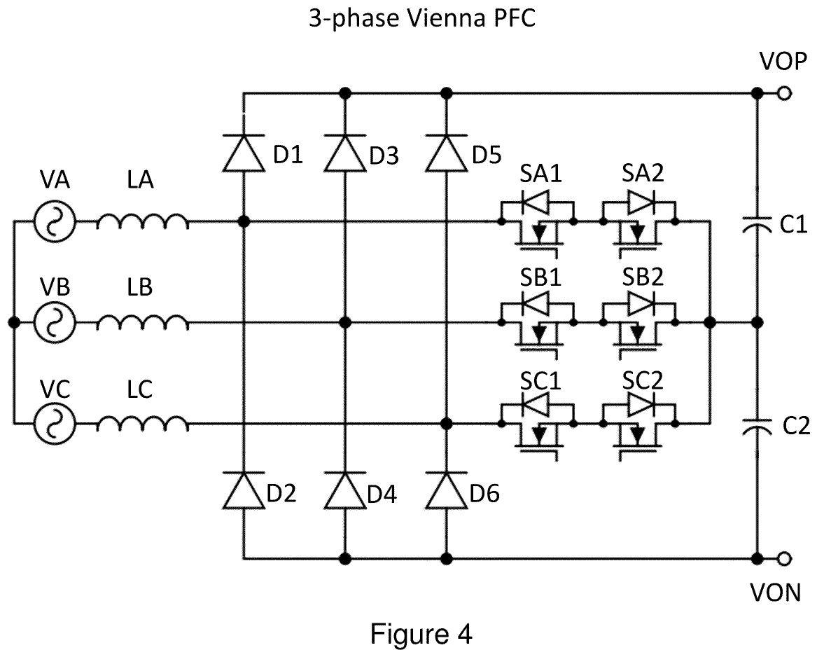

FIG. 4 illustrates a schematic diagram of a second implementation of the first power factor correction converter shown in FIG. 1 in accordance with various embodiments of the present disclosure. In some embodiments, the first power factor correction converter is implemented as a three-phase Vienna rectifier. It is alternatively referred to as a Vienna PFC as shown in FIG. 4.

In some embodiments, the three-phase ac source comprises a first phase ac source VA, a second phase ac source VB and a third phase ac source VC. The Vienna PFC comprises inductors LA, LB and LC, diodes D1, D2, D3, D4, D5 and D6, switches SA1, SA2, SB1, SB2, SC1 and SC2, and capacitors C1 and C2. D1 and D2 are connected in series between VOP and VON. D3 and D4 are connected in series between VOP and VON. D5 and D6 are connected in series between VOP and VON. C1 and C2 are connected in series between VOP and VON. LA is connected between VA, and a common node of D1 and D2. LB is connected between VB, and a common node of D3 and D4. LC is connected between VC, and a common node of D5 and D6. SA1 and SA2 are connected in series between the common node of D1 and D2, and a common node of C1 and C2. SB1 and SB2 are connected in series between the common node of D3 and D4, and the common node of C1 and C2. SC1 and SC2 are connected in series between the common node of D5 and D6, and the common node of C1 and C2.

The Vienna PFC employs a three-level structure, which reduces the voltage stress on components and allows for the use of lower-rated switches. This topology contributes to higher efficiency and lower electromagnetic interference (EMI). The Vienna PFC includes a combination of diodes and power switches as shown in FIG. 4. Suitable control algorithms are employed manage the switching to ensure that the ac input current remains sinusoidal and in phase with the input voltage.

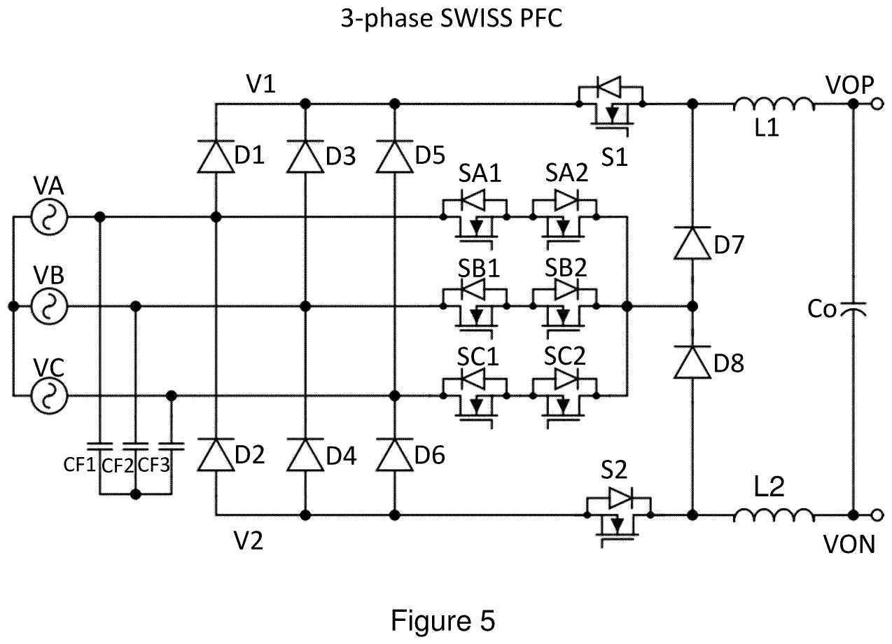

FIG. 5 illustrates a schematic diagram of a third implementation of the first power factor correction converter shown in FIG. 1 in accordance with various embodiments of the present disclosure. In some embodiments, the first power factor correction converter is implemented as a three-phase Swiss rectifier. It is alternatively referred to as a Swiss PFC as shown in FIG. 5.

The Swiss PFC comprises capacitors CF1, CF2 and CF3, diodes D1, D2, D3, D4, D5, D6, D7 and D8, switches SA1, SA2, SB1, SB2, SC1, SC2, S1 and S2, inductors L1 and L2, and output capacitor Co. CF1, CF2 and CF3 are connected to VA, VB and VC, respectively. D1 and D2 are connected in series between V1 and V2. D3 and D4 are connected in series between V1 and V2. D5 and D6 are connected in series between V1 and V2. Co is connected between VOP and VON. S1 and L1 are connected in series between V1 and VOP. S2 and L2 are connected in series between V2 and VON. D7 and D8 are connected in series between a common node of S1 and L1, and a common node of S2 and L2. SA1 and SA2 are connected in series between the common node of D1 and D2, and a common node of D7 and D8. SB1 and SB2 are connected in series between the common node of D3 and D4, and the common node of D7 and D8. SC1 and SC2 are connected in series between the common node of D5 and D6, and the common node of D7 and D8.

The Swiss PFC combines the benefits of passive and active PFC approaches. The Swiss PFC includes a combination of diodes and power switches to achieve precise power conversion. In operation, the Swiss PFC is configured to operate with three-phase ac input, making it suitable for high-power applications. This configuration balances the load across the three phases, improving efficiency and reducing EMI.

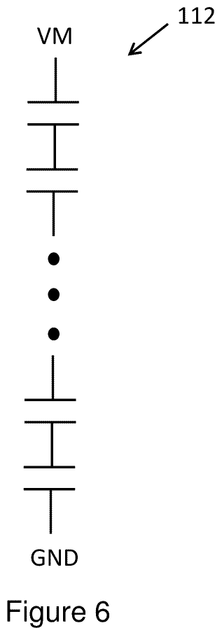

FIG. 6 illustrates a schematic diagram of a first implementation of the supercapacitor-based energy storage apparatus shown in FIG. 1 in accordance with various embodiments of the present disclosure. The supercapacitor-based energy storage apparatus 112 comprises a plurality of supercapacitors connected in series between VM and ground.

As illustrated in FIG. 6, the supercapacitors are connected to the intermediate voltage bus VM, which, in some embodiments, operates at approximately 400 V. At this voltage level, the current flowing to and from the supercapacitors remains relatively low, simplifying the system design. The intermediate voltage bus VM also reduces the number of holdup capacitors required, allowing for the efficient integration of supercapacitors into the power supply system.

The incorporation of a liquid cooling system in the energy storage system enables the implementation of the supercapacitor-based energy storage apparatus 112, which offer superior performance compared to conventional electrolytic capacitors. The liquid cooling system maintains the temperature of the supercapacitors below a predetermined threshold, such as 35 degrees Celsius. This controlled thermal environment ensures the reliability and longevity of the supercapacitors, allowing them to handle higher energy densities and rapid charge/discharge cycles without degradation.

The liquid cooling system can be implemented in various configurations to optimize thermal management for different operational needs. For instance, the system may specifically target the supercapacitors, maintaining their temperature to ensure high-performance operation. Alternatively, the liquid cooling system can be extended to encompass the entire device, including other heat-generating components such as power converters and processors. Cooling the entire device ensures a uniform thermal profile, reducing localized hotspots and enhancing the overall system reliability. This cooling approach can also simplify the system design by eliminating the need for multiple independent cooling solutions.

By utilizing liquid cooling, the system is able to integrate supercapacitors as a key component of the energy storage architecture. The cooling system not only enhances the performance of the supercapacitors but also supports their ability to deliver hold-up times during power interruptions.

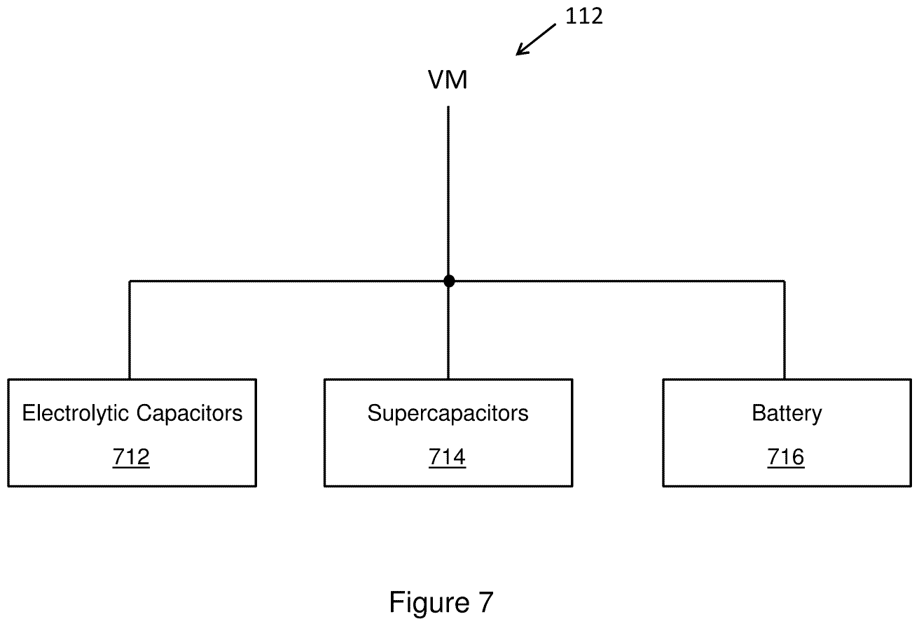

FIG. 7 illustrates a block diagram of a second implementation of the supercapacitor-based energy storage apparatus shown in FIG. 1 in accordance with various embodiments of the present disclosure. As shown in FIG. 7, electrolytic capacitors, supercapacitors, and batteries are connected to the intermediate voltage bus VM. Each energy storage device is configured to provide hold-up time for different durations, depending on the nature of the power interruption and the specific system requirements.

As shown in FIG. 7, the intermediate voltage bus VM operates at a high voltage, such as approximately 400 V. Electrolytic capacitors, supercapacitors, and batteries are connected in parallel to the intermediate voltage bus VM, each optimized for distinct operational roles.

Electrolytic capacitors 712 provide immediate, short-duration hold-up times during transient power interruptions. Their high-power density enables rapid discharge to stabilize the voltage on VM.

Supercapacitors 714 are positioned as an intermediary solution. The supercapacitors 714 deliver energy over medium-duration hold-up times. Their rapid charge/discharge capabilities and higher energy density compared to electrolytic capacitors make them ideal for bridging gaps that exceed the electrolytic capacitor's capabilities but do not yet require battery intervention.

Batteries 716 are employed for extended hold-up times during prolonged power outages. While their response time is slower than that of capacitors, their energy density allows them to sustain the load for a longer duration, ensuring continuous operation until the primary power source is restored.

In operation, the system dynamically utilizes the appropriate energy storage device based on the duration and intensity of the power interruption. During brief interruptions, the electrolytic capacitors discharge rapidly to stabilize VM. For intermediate hold-up times, the supercapacitors discharge to maintain stable power delivery. In the case of extended outages, the batteries are activated to supply energy, ensuring uninterrupted operation of the load.

The intermediate voltage bus VM allows these devices to operate with relatively low current, simplifying system design and reducing conduction losses. By connecting electrolytic capacitors, supercapacitors, and batteries in parallel, the system achieves a scalable and flexible architecture capable of addressing a wide range of hold-up time requirements.

The incorporation of a liquid cooling system in the energy storage system enables the implementation of the supercapacitors 714, which offer superior performance compared to conventional electrolytic capacitors. The liquid cooling system maintains the temperature of the supercapacitors below a predetermined threshold, such as 35 degrees Celsius. This controlled thermal environment ensures the reliability and longevity of the supercapacitors, allowing them to handle higher energy densities and rapid charge/discharge cycles without degradation.

In addition to enhancing the performance of supercapacitors, the liquid cooling system also facilitates the thermal management of batteries integrated into the energy storage system. The liquid cooling system ensures that both supercapacitors and batteries are maintained below a temperature threshold of 35 degrees Celsius, thereby optimizing their efficiency and lifespan.

The liquid cooling system can be implemented to target specific components, such as supercapacitors and batteries, or to provide comprehensive thermal management for the entire device. Targeted cooling focuses on maintaining optimal operating temperatures for the supercapacitors and batteries, ensuring they deliver medium-duration and extended-duration hold-up times, respectively. Conversely, implementing liquid cooling for the entire device can provide uniform temperature control across all critical components, including power converters and processors, in addition to the energy storage devices. This configuration minimizes the risk of thermal stress, improves system performance, and ensures reliable operation during various power interruption scenarios.

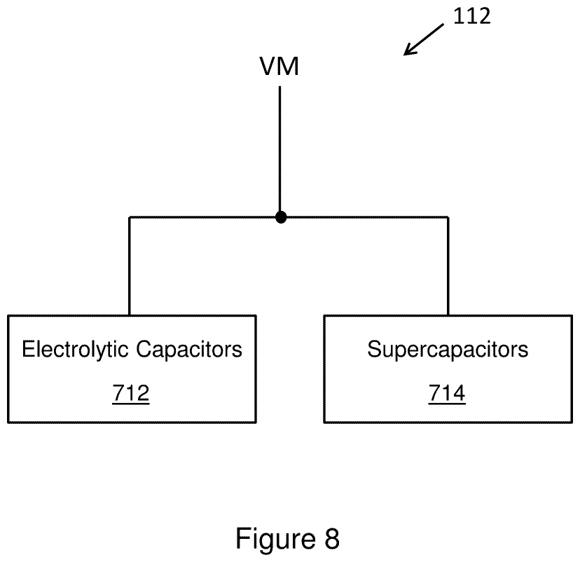

FIG. 8 illustrates a block diagram of a third implementation of the supercapacitor-based energy storage apparatus shown in FIG. 1 in accordance with various embodiments of the present disclosure. As shown in FIG. 8, electrolytic capacitors and supercapacitors are connected to the intermediate voltage bus VM. Each energy storage device is configured to provide hold-up time for different durations, depending on the nature of the power interruption and the specific system requirements.

As shown in FIG. 8, the intermediate voltage bus VM operates at a high voltage, such as approximately 400 V. Electrolytic capacitors and supercapacitors are connected in parallel to the intermediate voltage bus VM, each optimized for distinct operational roles.

Electrolytic capacitors 712 provide immediate, short-duration hold-up times (e.g., less than 1 second) during transient power interruptions. Their high-power density enables rapid discharge to stabilize the voltage on VM.

Supercapacitors 714 provide long-duration hold-up times (e.g., greater than 1 second) during transient power interruptions. The supercapacitors 714 deliver energy over medium-duration hold-up times. Their rapid charge/discharge capabilities and higher energy density compared to electrolytic capacitors make them ideal for bridging gaps that exceed the electrolytic capacitor's capabilities.

In operation, the system dynamically utilizes the appropriate energy storage device based on the duration and intensity of the power interruption. During brief interruptions, the electrolytic capacitors discharge rapidly to stabilize VM. For long hold-up times, the supercapacitors discharge to maintain stable power delivery.

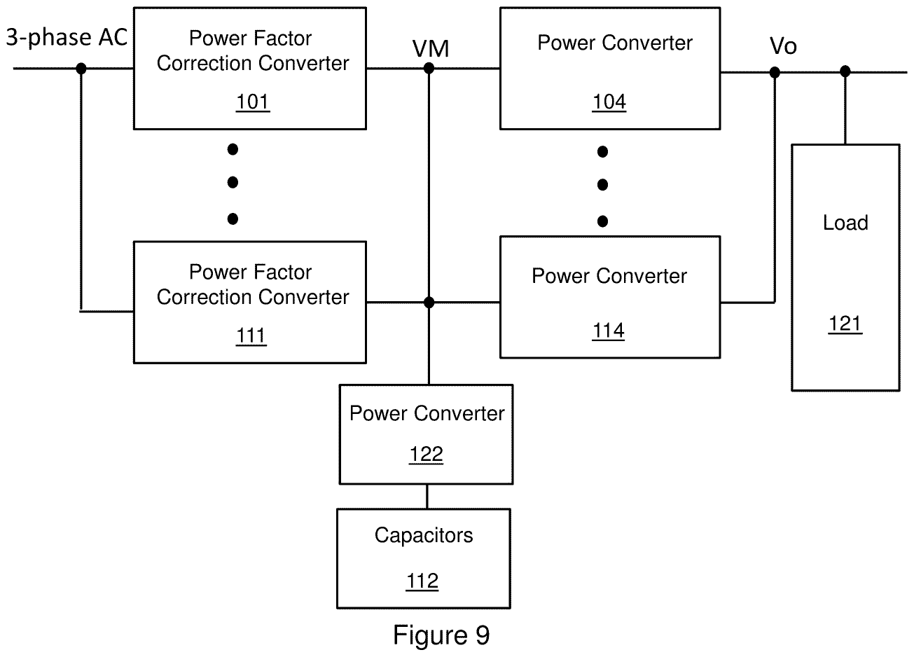

FIG. 9 illustrates a block diagram of a second implementation of a power conversion system in accordance with various embodiments of the present disclosure. The system configuration of FIG. 9 is similar to that shown in FIG. 1 except that a power converter 122 is connected between VM and the capacitors 112.

The inclusion of the power converter 122 between VM and the capacitors 112 offers a significant advantage in reducing the physical size and volume of the energy storage system. Without the power converter 122, energy storage devices would need to operate directly at the intermediate voltage bus level, such as 400 V. This would require a larger number of energy storage units, or capacitors with higher voltage ratings, to handle the voltage directly, leading to increased system size and complexity.

By integrating the power converter 122, energy storage devices can operate at a much lower voltage, such as 50 V. This allows for a more compact energy storage design since lower voltage energy storage devices typically require less space. The power converter 122 efficiently boosts the voltage as energy is transferred from the storage to the intermediate voltage bus VM, enabling the system to maintain the required high-voltage operation at VM while minimizing the footprint of the energy storage. This approach not only optimizes the use of space but also simplifies the mechanical design and integration of the energy storage system into the overall device.

In some embodiments, the power converter 122 is implemented as a bidirectional power converter. The bidirectional converter can be coupled at different locations of the power conversion system, including the ac side of the power factor correction converters, the dc bus (intermediate voltage bus or output voltage bus), and the dc load terminal, to adapt to diverse system configuration requirements. In operation, the bidirectional power converter is configured to provide energy to the intermediate voltage bus through discharging the plurality of energy storage devices in the event of an ac power loss. During normal operation, the bidirectional power converter is configured to extract energy from the intermediate voltage bus through charging the plurality of energy storage devices.

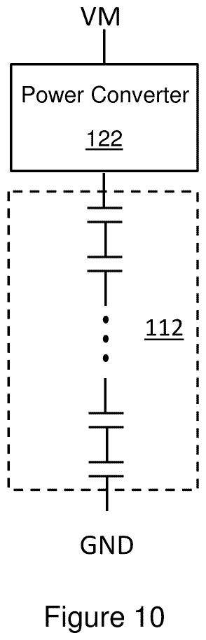

FIG. 10 illustrates a block diagram of a first implementation of the system shown in FIG. 9 in accordance with various embodiments of the present disclosure. The system incorporates a bidirectional converter 122 and a plurality of supercapacitors 112. As shown in FIG. 10, the bidirectional converter 122 is connected between the supercapacitors 112 and the intermediate voltage bus VM.

In operation, the bidirectional converter facilitates the integration of supercapacitors into the power delivery system. When the power supply experiences an ac input loss, the bidirectional power converter 122 discharges energy stored in the supercapacitors to the intermediate voltage bus VM, ensuring stable power delivery to the load. During normal operation, the bidirectional power converter 122 recharges the supercapacitors 112 from the intermediate voltage bus VM, preparing them for subsequent power interruptions. Alternatively, the existing circuits of the power conversion system, such as the PFC ac/dc circuit or the dc/dc power converter, can be reused to charge and discharge the capacitors (electrolytic capacitors and supercapacitors) without requiring additional independent charging/discharging circuits, simplifying the system design and reducing costs.

As illustrated in FIG. 10, the supercapacitors are coupled to the high-voltage bus VM, which, in some embodiments, operates at approximately 400 V. At this voltage level, the current flowing to and from the supercapacitors remains relatively low because of the bidirectional converter, simplifying the system design. The bidirectional converter which VM travels through also reduces the number of holdup capacitors required, allowing for the efficient integration of supercapacitors into the power supply system.

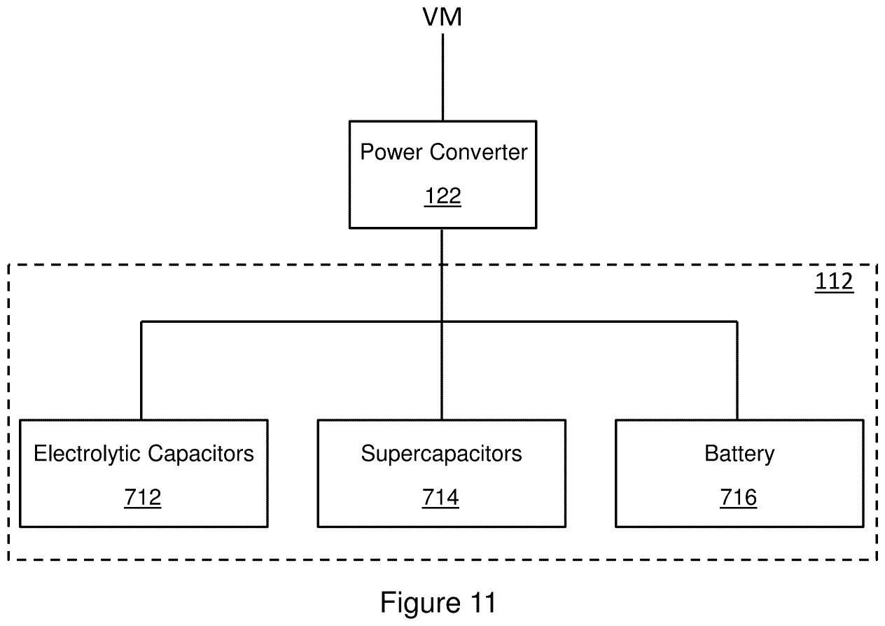

FIG. 11 illustrates a block diagram of a second implementation of the system shown in FIG. 9 in accordance with various embodiments of the present disclosure. The addition of the bidirectional power converter 122 enables more precise energy management and improves the efficiency of energy transfer between the energy storage devices and VM.

As shown in FIG. 11, the intermediate voltage bus VM operates at a high voltage, such as approximately 400 V. The bidirectional power converter 122 is connected between VM and the energy storage devices, including electrolytic capacitors 712, supercapacitors 714, and batteries 716, allowing for optimized energy flow based on system requirements.

Electrolytic capacitors 712 provide immediate, short-duration hold-up times during transient power interruptions. The bidirectional power converter 122 enables controlled discharge of the capacitors to stabilize the voltage on VM and ensures efficient recharging during normal operation.

Supercapacitors 714 deliver energy over medium-duration hold-up times. The bidirectional power converter 122 regulates the charge and discharge of the supercapacitors, leveraging their rapid energy exchange capabilities to bridge gaps longer than those managed by electrolytic capacitors but shorter than those requiring battery intervention.

Batteries 716 are employed for extended hold-up times during prolonged power outages. The bidirectional power converter 122 facilitates the seamless integration of batteries, managing their slower response times and high energy density to sustain the load for extended durations until the primary power source is restored.

In operation, the bidirectional power converter 122 dynamically coordinates energy flow between VM and the energy storage devices. During brief interruptions, it prioritizes the rapid discharge of electrolytic capacitors to stabilize VM. For intermediate hold-up times, it transitions to the supercapacitors to maintain stable power delivery. In the case of extended outages, the converter engages the batteries to ensure uninterrupted operation of the load.

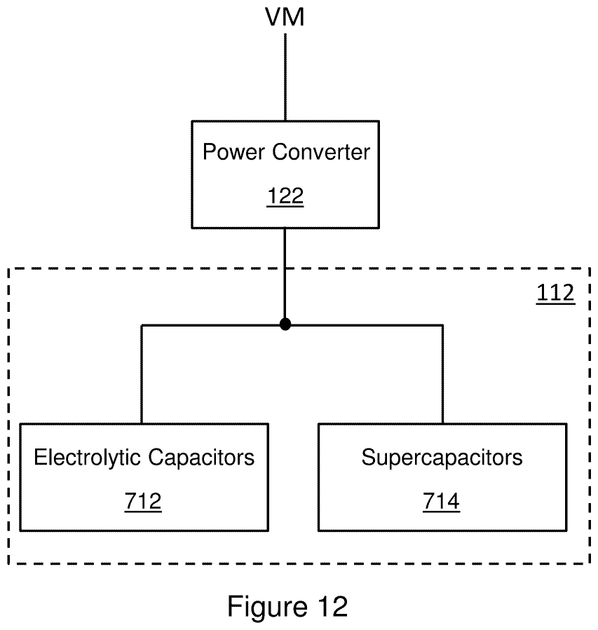

FIG. 12 illustrates a block diagram of a third implementation of the system shown in FIG. 9 in accordance with various embodiments of the present disclosure. In this embodiment, a bidirectional power converter 122 is incorporated to interface between the intermediate voltage bus VM and the energy storage devices. The inclusion of the bidirectional power converter 122 provides enhanced controllability over energy exchange and improves overall system efficiency.

As illustrated in FIG. 12, the intermediate voltage bus VM is maintained at a relatively high dc voltage level, for example on the order of 400 V. The bidirectional power converter 122 is electrically coupled between VM and a combination of energy storage devices, including electrolytic capacitors 712 and supercapacitors 714. This configuration enables controlled bidirectional energy transfer between the intermediate voltage bus and the energy storage devices in response to operating conditions.

The electrolytic capacitors 712 are configured to support short-duration energy demands, such as those arising during brief power interruptions or transient disturbances. Through the bidirectional power converter 122, energy stored in the electrolytic capacitors 712 can be selectively released to regulate the voltage on VM, and the capacitors can be efficiently recharged when normal power conditions are restored.

The supercapacitors 714 are configured to supply energy over extended time intervals, thereby supporting longer hold-up requirements. The bidirectional power converter 122 manages the charging and discharging of the supercapacitors 714, taking advantage of their high-power density and fast response characteristics to sustain the voltage on VM for durations exceeding those supported by the electrolytic capacitors.

In operation, the bidirectional power converter 122 adaptively controls the distribution of energy between the intermediate voltage bus VM and the energy storage devices. For short-term events, energy delivery from the electrolytic capacitors 712 is emphasized to quickly stabilize VM, while for longer-duration events, energy delivery is shifted toward the supercapacitors 714 to maintain continuous and stable power to the system.

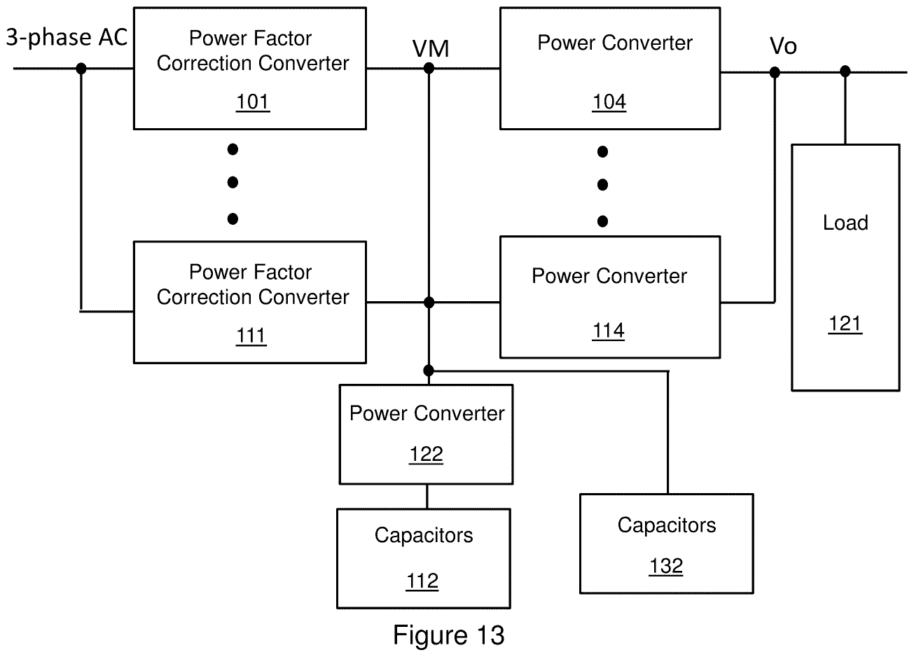

FIG. 13 illustrates a block diagram of a third implementation of a power conversion system in accordance with various embodiments of the present disclosure. The system configuration of FIG. 13 is similar to that shown in FIG. 9 except that some capacitors 132 are connected to VM directly. More particularly, the capacitors 132 are implemented as electrolytic capacitors. The capacitors 112 are implemented as supercapacitors or a combination of supercapacitors and batteries.

The configuration of directly connecting the intermediate voltage bus VM to the electrolytic capacitors provides significant advantages. First, electrolytic capacitors usually inherently possess the capability to achieve the required voltage rating, such as 400 V, without necessitating additional voltage boosting. Second, as the primary energy storage component utilized during hold-up events, the direct connection eliminates the delay associated with intermediary power converters, enabling the electrolytic capacitors to discharge rapidly and effectively stabilize the intermediate voltage bus to meet system requirements.

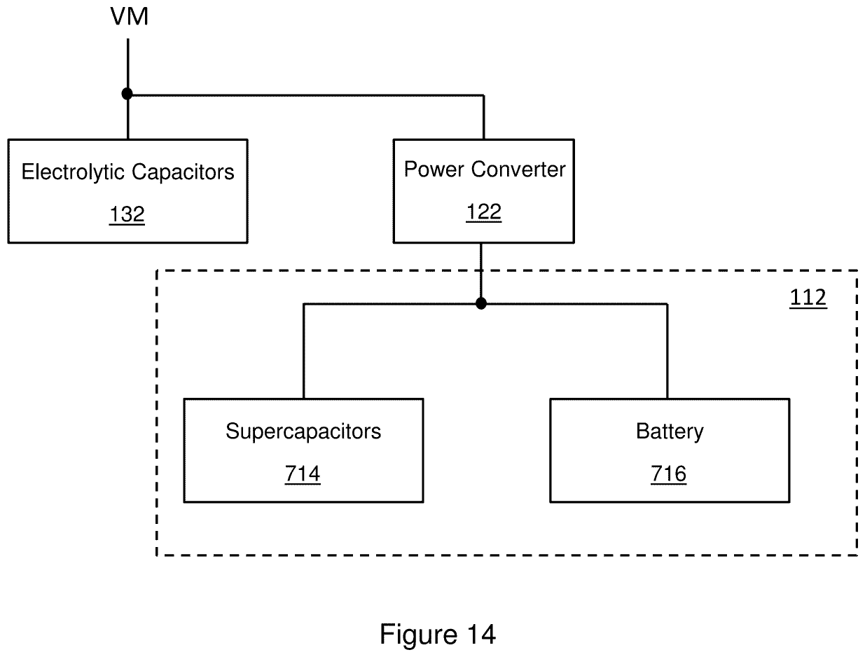

FIG. 14 illustrates a block diagram of a first implementation of the system shown in FIG. 13 in accordance with various embodiments of the present disclosure. This system configuration shown in FIG. 14 enhances the overall energy management by allowing for flexible power flow between the voltage source, energy storage devices, and the intermediate voltage bus VM, optimizing system efficiency.

As shown in FIG. 14, the intermediate voltage bus VM operates at a high voltage, such as approximately 400 V. The electrolytic capacitors 712 are directly connected to VM, providing immediate voltage stabilization during short-duration interruptions. Meanwhile, the bidirectional power converter 122 controls the energy flow between VM and the energy storage devices, including the supercapacitors 714 and batteries 716, enabling efficient charging and discharging based on system needs.

Electrolytic capacitors 712 serve to smooth out voltage fluctuations and provide transient hold-up times. The direct connection between VM and electrolytic capacitors ensures that any rapid changes in voltage are absorbed and stabilized quickly, allowing for a smoother operation of the system.

Supercapacitors 714 are used for medium-duration hold-up times. The bidirectional power converter 122 regulates the charging and discharging of the supercapacitors, utilizing their fast charge/discharge cycles to provide energy when there is a temporary power deficit, thus bridging the gap between short-term and long-term energy needs.

Batteries 716 are designed for extended hold-up times and are charged and discharged more slowly. The bidirectional power converter 122 efficiently manages energy flow to and from the batteries, ensuring that they are used when necessary to support the system during prolonged outages or when the power source is insufficient.

In operation, the bidirectional power converter 122 dynamically manages energy flow between VM and the energy storage devices. During short interruptions, it relies on the electrolytic capacitors to quickly stabilize the voltage. For medium-duration hold-ups, it utilizes the supercapacitors, and for longer power interruptions, the converter draws energy from the batteries. This coordinated approach ensures continuous and efficient power delivery, enhancing the overall reliability of the system.

The supercapacitor is an energy storage device that bridges the gap between capacitors and rechargeable batteries. It offers high power density, rapid charge and discharge capabilities, and a long cycle life, making it suitable for applications requiring bursts of energy or quick storage and release. Supercapacitors store energy using an electrochemical double-layer mechanism, enabling much higher capacitance than traditional capacitors. Unlike batteries, supercapacitors can be charged or discharged in seconds due to their low internal resistance. Supercapacitors are often integrated with batteries to leverage the strengths of both technologies, such as energy density from batteries and high-power delivery from supercapacitors.

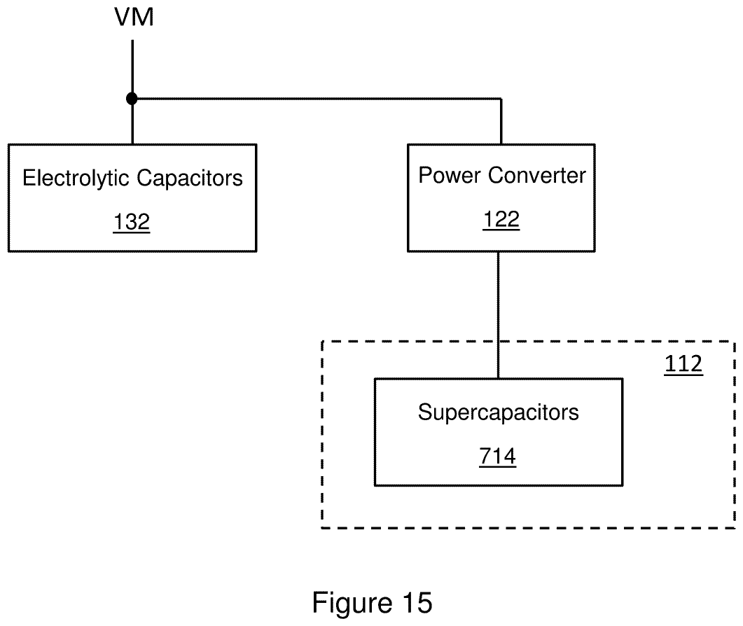

FIG. 15 illustrates a block diagram of a second implementation of the system shown in FIG. 13 in accordance with various embodiments of the present disclosure. In this embodiment, the system architecture is arranged to support flexible and coordinated energy exchange among a voltage source, an intermediate voltage bus VM, and multiple energy storage elements. This arrangement improves overall energy utilization and supports efficient power regulation under varying operating conditions.

As illustrated in FIG. 15, the intermediate voltage bus VM is maintained at a relatively high dc voltage level, for example approximately 400 V. A set of electrolytic capacitors 712 is directly coupled to VM, enabling immediate response to voltage disturbances and short-duration power interruptions. In parallel, a bidirectional power converter 122 interfaces VM with additional energy storage devices, including supercapacitors 714, to provide controlled bidirectional energy transfer.

By being directly connected to the intermediate voltage bus VM, the electrolytic capacitors 712 function as a primary buffer for rapid voltage transients. This direct coupling allows the electrolytic capacitors 712 to absorb sudden energy fluctuations and suppress voltage ripple on VM, thereby promoting stable operation of downstream circuitry.

The supercapacitors 714 are configured to support energy delivery over longer time intervals. Through operation of the bidirectional power converter 122, the supercapacitors 714 are selectively charged and discharged, making use of their high-power capability and fast response characteristics to supplement the energy provided by the electrolytic capacitors when extended hold-up is required.

During system operation, the bidirectional power converter 122 adaptively governs energy exchange between the intermediate voltage bus VM and the energy storage devices. For brief disturbances, voltage regulation is primarily maintained by the electrolytic capacitors 712. When longer-duration energy support is needed, the bidirectional power converter 122 engages the supercapacitors 714 to sustain power delivery. This coordinated energy management approach enhances system stability, efficiency, and reliability.

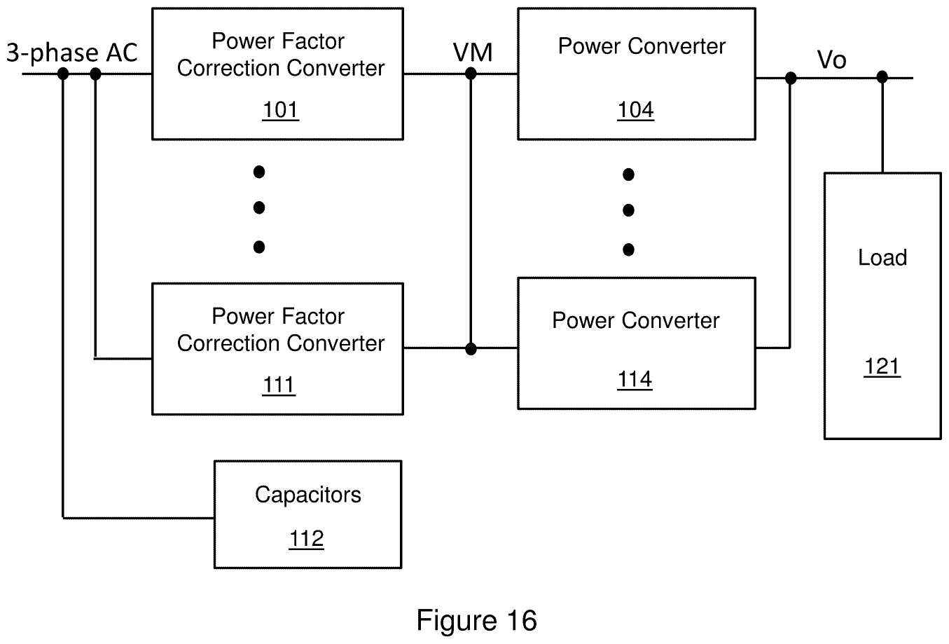

FIG. 16 illustrates a block diagram of a fourth implementation of a power conversion system in accordance with various embodiments of the present disclosure. The system configuration of FIG. 16 is similar to that shown in FIG. 1 except that the capacitors 112 are connected to the input terminal of the power factor correction converters.

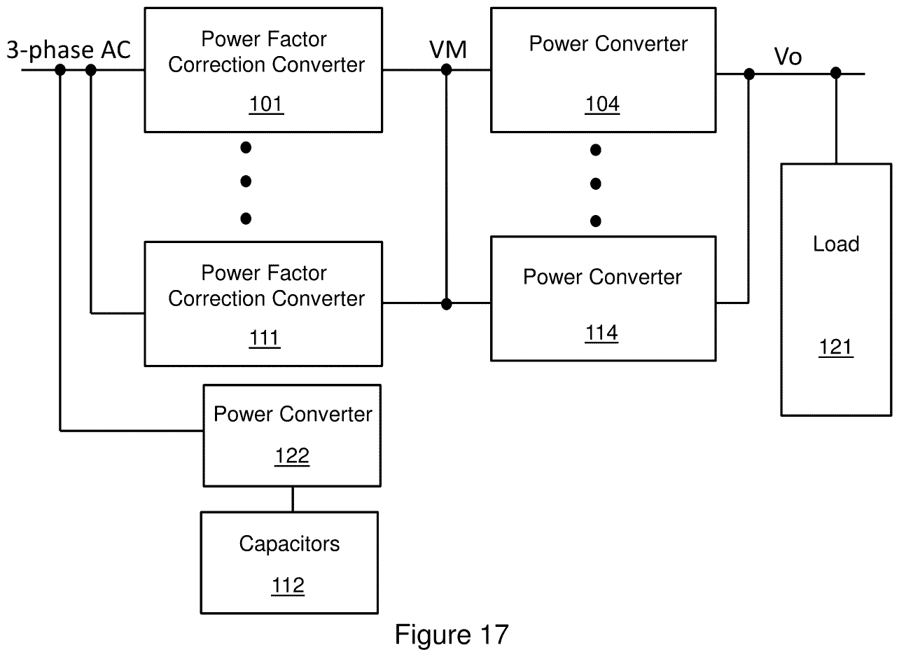

FIG. 17 illustrates a block diagram of a fifth implementation of a power conversion system in accordance with various embodiments of the present disclosure. The system configuration of FIG. 17 is similar to that shown in FIG. 9 except that the capacitors 112 and the power converter 122 are connected to the input terminal of the power factor correction converters.

In some embodiments, all of the capacitors 112 are coupled to the input terminal through the power converter 122. In other embodiments, a first portion of the capacitors 112 is directly connected to the input terminal, while a second portion of the capacitors 112 is coupled to the input terminal through the power converter 122, as described in connection with other embodiments (e.g., the embodiments shown in FIGS. 14-15) of the present disclosure.

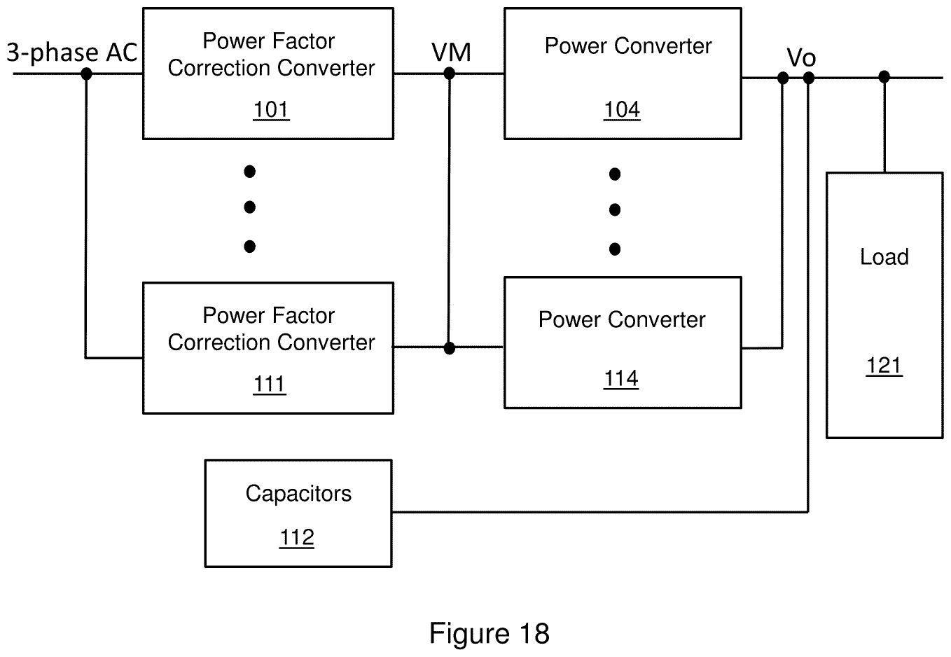

FIG. 18 illustrates a block diagram of a sixth implementation of a power conversion system in accordance with various embodiments of the present disclosure. The system configuration of FIG. 18 is similar to that shown in FIG. 1 except that the capacitors 112 are connected to the output voltage bus Vo.

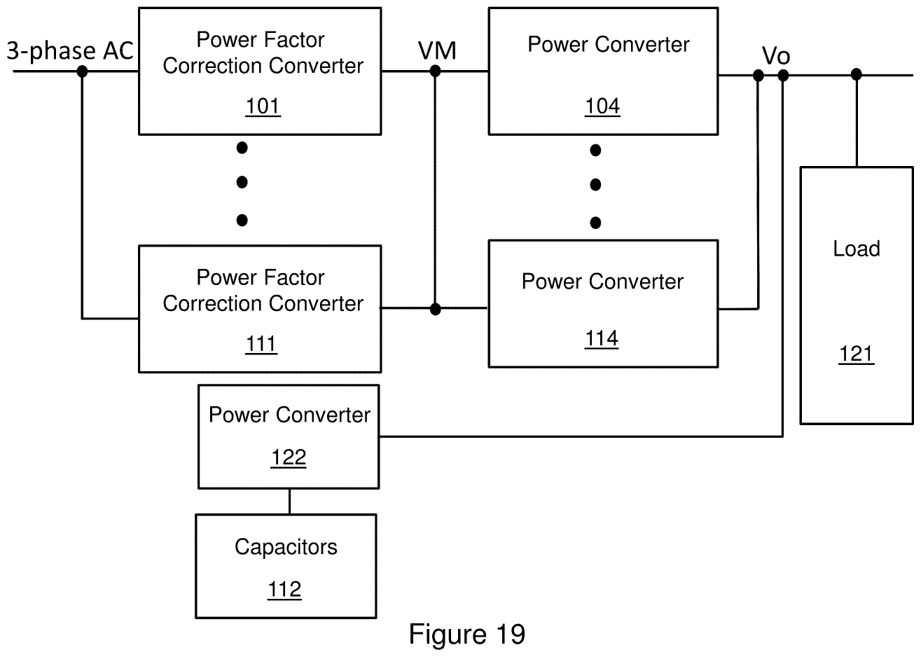

FIG. 19 illustrates a block diagram of a seventh implementation of a power conversion system in accordance with various embodiments of the present disclosure. The system configuration of FIG. 19 is similar to that shown in FIG. 9 except that the capacitors 112 and the power converter 122 are connected to the output voltage bus Vo.

In some embodiments, all of the capacitors 112 are coupled to the output voltage bus Vo through the power converter 122. In other embodiments, a first portion of the capacitors 112 is directly connected to the output voltage bus Vo, while a second portion of the capacitors 112 is coupled to the output voltage bus Vo through the power converter 122, as described in connection with other embodiments (e.g., the embodiments shown in FIGS. 14-15) of the present disclosure.

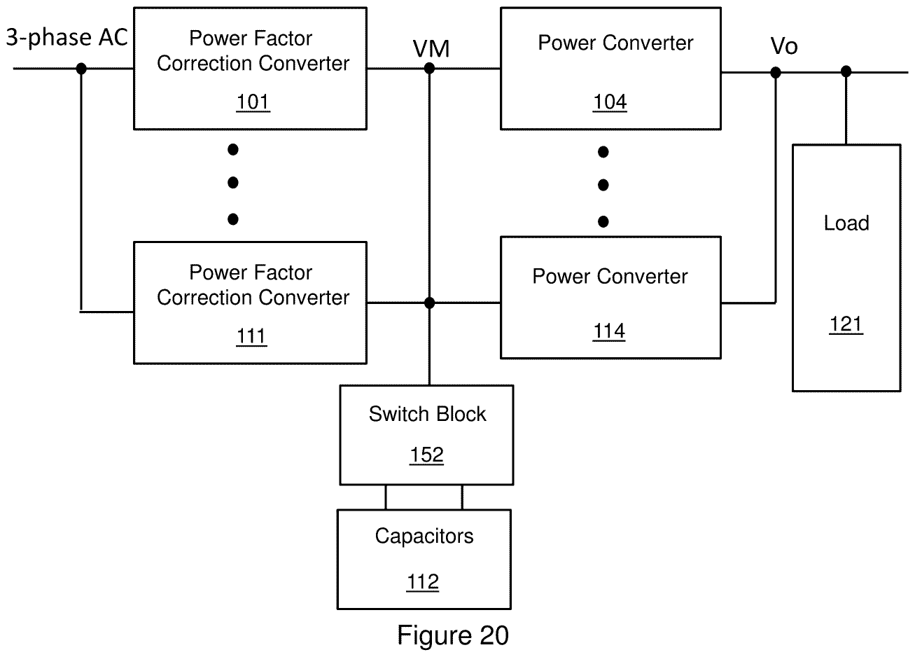

FIG. 20 illustrates a block diagram of an eighth implementation of a power conversion system in accordance with various embodiments of the present disclosure. In this embodiment, one or more capacitors 112 are selectively coupled to the intermediate voltage bus VM through a switch block 152. The switch block 152 comprises a plurality of controllable switches that enable the capacitors 112 to be connected to or disconnected from the intermediate voltage bus VM in a controlled manner, thereby providing flexible energy buffering and power management functionality.

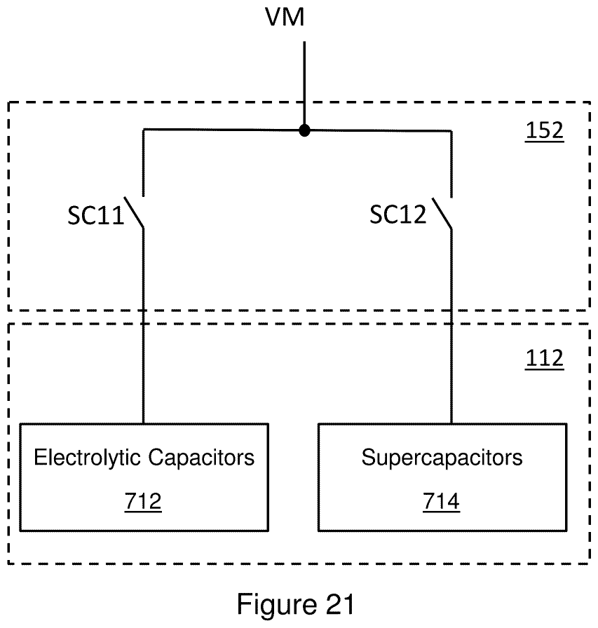

FIG. 21 illustrates a block diagram of a first implementation of the system shown in FIG. 20 in accordance with various embodiments of the present disclosure. As shown in FIG. 21, the switch block 152 includes a first controllable switch SC11 and a second controllable switch SC12 arranged to selectively couple the capacitors 112 to the intermediate voltage bus VM. In particular, the electrolytic capacitors 712 are connected to VM through SC11. The supercapacitors 714 are connected to VM through SC12. The first controllable switch SC11 and the second controllable switch SC12 may be independently actuated to control when the respective energy storage devices are electrically connected to the intermediate voltage bus VM.

In some embodiments, the first controllable switch SC11 and the second controllable switch SC12 are selectively controlled based on a duration of a power variation detected in the power conversion system. The power variation may be associated with, for example, a load transient, a change in input power, or a disturbance on the intermediate voltage bus VM. The duration of the power variation may be determined by monitoring voltage, current, power, or a combination thereof over time.

In operation, when the duration of the power variation is shorter than a predetermined time threshold, the control circuitry turns on the first controllable switch SC11 to connect the electrolytic capacitors 712 to the intermediate voltage bus VM, while maintaining the second controllable switch SC12 in an off state such that the supercapacitors 714 remain disconnected from the intermediate voltage bus VM. In this operating mode, the electrolytic capacitors 712 provide rapid energy buffering to suppress short-duration voltage fluctuations on the intermediate voltage bus VM.

In operation, when the duration of the power variation is greater than or equal to the predetermined time threshold, the control circuitry turns on both the first controllable switch SC11 and the second controllable switch SC12 to connect both the electrolytic capacitors 712 and the supercapacitors 714 to the intermediate voltage bus VM. In this operating mode, the supercapacitors supplement the electrolytic capacitors to provide sustained energy support for longer-duration power variations, thereby maintaining stability of the intermediate voltage bus VM.

The predetermined time threshold may be selected based on system requirements and characteristics of the energy storage devices, such as response speed, energy density, and lifetime considerations. In some embodiments, the predetermined time threshold is on the order of one second, although other threshold values may be used. By selectively engaging the electrolytic capacitors and the supercapacitors based on the duration of the power variation, the system achieves improved transient response, efficient energy utilization, and enhanced reliability.

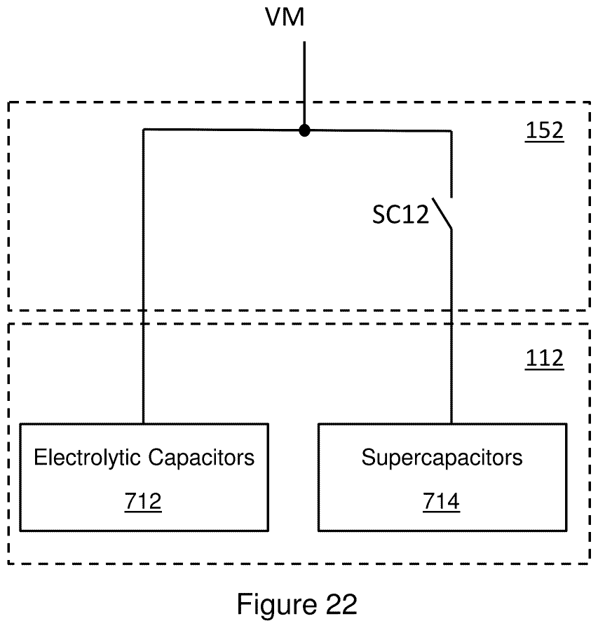

FIG. 22 illustrates a block diagram of a second implementation of the system shown in FIG. 20 in accordance with various embodiments of the present disclosure. The arrangement of the switch block 152 is similar to that shown in FIG. 21 except that the electrolytic capacitors 712 are connected to VM directly. In this alternative implementation, the first controllable switch may be omitted for the electrolytic capacitors.

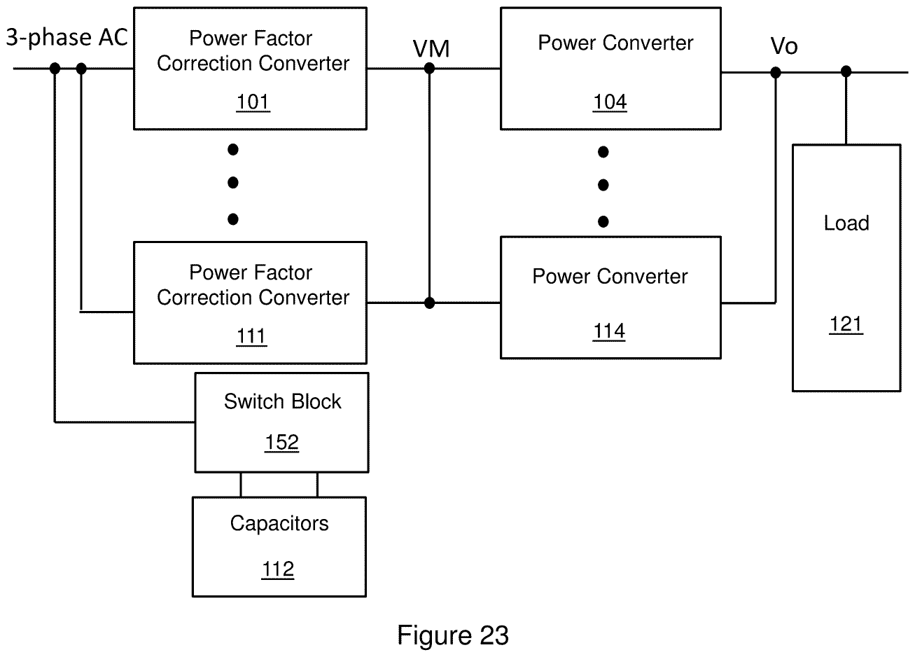

FIG. 23 illustrates a block diagram of a ninth implementation of a power conversion system in accordance with various embodiments of the present disclosure. In the embodiment of FIG. 23, the switch block 152 is coupled between the capacitors 112 and an input node of the power conversion system, such as an input terminal of a power factor correction converter. In this configuration, the capacitors 112 are selectively connected to the input node through the switch block 152 to absorb or supply energy at the input side of the system.

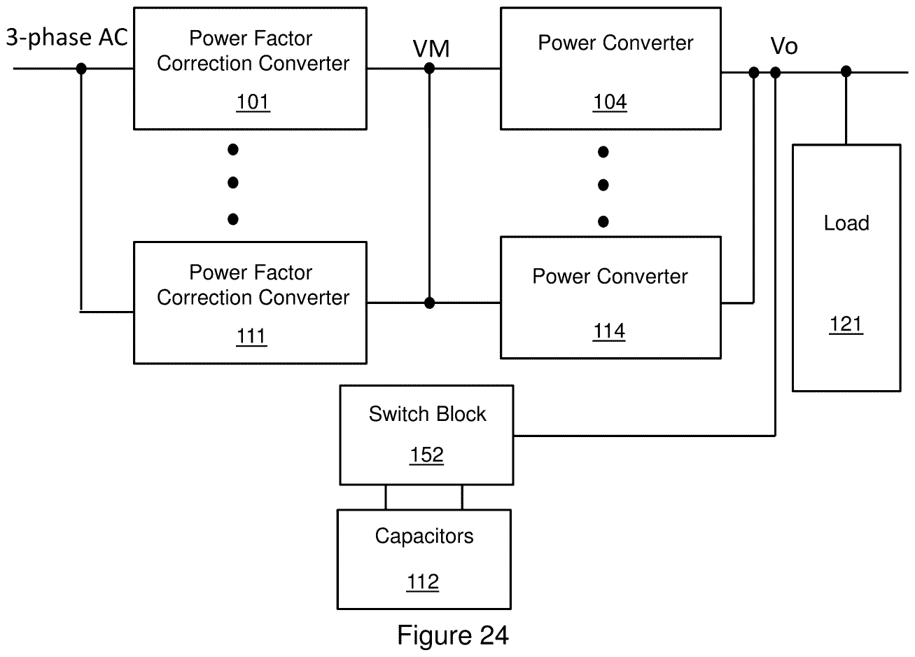

FIG. 24 illustrates a block diagram of a tenth implementation of a power conversion system in accordance with various embodiments of the present disclosure. In this embodiment, the switch block 152 is coupled between the capacitors 112 and an output node of the power conversion system. The capacitors 112 are selectively connected to the output node through the switch block 152 to provide energy buffering, voltage stabilization, or transient power support at the output side of the system.

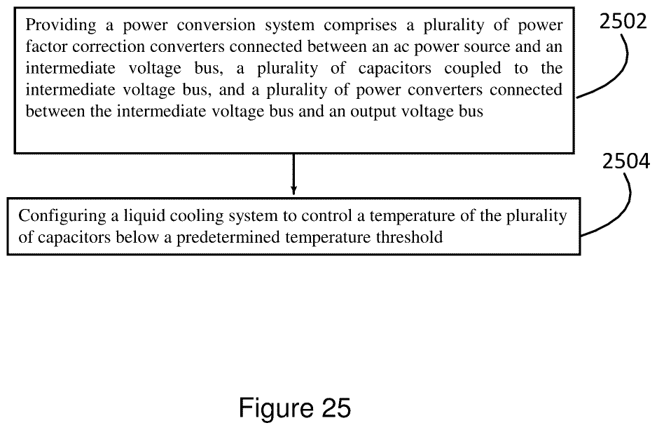

FIG. 25 illustrates a flow chart of a method for configuring the power conversion system shown in FIG. 1 in accordance with various embodiments of the present disclosure. This flowchart shown in FIG. 25 is merely an example, which should not unduly limit the scope of the claims. One of ordinary skill in the art would recognize many variations, alternatives, and modifications. For example, various steps illustrated in FIG. 25 may be added, removed, replaced, rearranged and repeated.

As shown in FIG. 25, at step 2502, a power conversion system is provided. The power conversion system comprises a plurality of power factor correction converters connected between an ac power source and an intermediate voltage bus, a plurality of capacitors that in implementation consists of a combination of a plurality of electrolytic capacitors 712, a plurality of supercapacitors 714, and a plurality of batteries 716. The plurality of capacitors is coupled to the intermediate voltage bus, and a plurality of power converters 104 connected between the intermediate voltage bus and an output voltage bus.

At step 2504, the liquid cooling system is configured to control a temperature of the plurality of capacitors below a predetermined temperature threshold.

In some embodiments, the predetermined temperature threshold is 35 degrees, and the plurality of capacitors is implemented as a plurality of supercapacitors connected in series.

In some embodiments, the power conversion system further comprises a plurality of electrolytic capacitors coupled to the intermediate voltage bus, and a plurality of batteries coupled to the intermediate voltage bus.

The method further comprises providing a bidirectional power converter having first input/output terminals connected to the intermediate voltage bus and second input/output terminals connected to the plurality of supercapacitors, the plurality of electrolytic capacitors and the plurality of batteries, and configuring the bidirectional power converter to manage energy flow between the intermediate voltage bus and the plurality of electrolytic capacitors, the plurality of supercapacitors, and the plurality of batteries, wherein the plurality of electrolytic capacitors is configured to provide immediate voltage stabilization by mitigating rapid voltage fluctuations during short duration interruptions, the plurality of supercapacitors is configured to address medium-duration power deficits by leveraging their high power density and rapid charge-discharge capabilities, and the plurality of batteries is configured to deliver sustained energy support for extended hold-up times, ensuring continuous system operation during prolonged power interruptions.

Although embodiments of the present disclosure and its advantages have been described in detail, it should be understood that various changes, substitutions and alterations can be made herein without departing from the spirit and scope of the disclosure as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A power conversion system comprising:
a plurality of power factor correction converters connected between an ac power source and an intermediate voltage bus;
a plurality of capacitors coupled to the intermediate voltage bus, wherein the plurality of capacitors is configured as holdup capacitors and a temperature of the plurality of capacitors is controlled by a liquid cooling system; and
a plurality of power converters connected between the intermediate voltage bus and an output voltage bus.

2. The power conversion system of claim 1, wherein:
a plurality of processors is coupled to the output voltage bus, and
the plurality of processors is a plurality of artificial intelligence (AI) processors.

3. The power conversion system of claim 1, wherein:
the intermediate voltage bus is of a voltage of about 400 V.

4. The power conversion system of claim 1, wherein:
the plurality of capacitors is implemented as a plurality of supercapacitors connected in series.

5. The power conversion system of claim 1, further comprising:
a plurality of electrolytic capacitors connected to the intermediate voltage bus; and
a plurality of batteries connected to the intermediate voltage bus.

6. The power conversion system of claim 1, further comprising:
a bidirectional converter coupled between the intermediate voltage bus and the plurality of capacitors, wherein:
the bidirectional converter is configured to discharge energy from the plurality of capacitors to the intermediate voltage bus during transient power interruptions, thereby stabilizing the intermediate voltage bus; and
the bidirectional converter is configured to recharge the plurality of capacitors from the intermediate voltage bus during normal operation, maintaining the plurality of capacitors in a charged state for subsequent interruptions.

7. The power conversion system of claim 1, further comprising:
a bidirectional converter coupled between the intermediate voltage bus and the plurality of capacitors, wherein the plurality of capacitors comprises:
a plurality of supercapacitors; and
a plurality of electrolytic capacitors, and wherein:
the bidirectional converter is configured to discharge energy from the plurality of capacitors to the intermediate voltage bus during transient power interruptions, thereby stabilizing the intermediate voltage bus; and
the bidirectional converter is configured to recharge the plurality of capacitors from the intermediate voltage bus during normal operation, maintaining the plurality of capacitors in a charged state for subsequent interruptions.

8. The power conversion system of claim 1, further comprising:
a bidirectional converter coupled between the intermediate voltage bus and the plurality of capacitors;
a plurality of electrolytic capacitors connected to the intermediate voltage bus; and
a plurality of batteries connected to the bidirectional converter.

9. The power conversion system of claim 1, wherein:
the cooling system is configured to provide a sealed housing to cool the plurality of capacitors.

10. The power conversion system of claim 1, wherein:
the cooling system is configured to provide a sealed housing to cool the plurality of power factor correction converters and the plurality of capacitors and the plurality of power converters.

11. A method comprising:
providing a power conversion system comprising a plurality of power factor correction converters connected between an ac power source and an intermediate voltage bus, a plurality of capacitors coupled to the intermediate voltage bus, and a plurality of power converters connected between the intermediate voltage bus and an output voltage bus; and
configuring a liquid cooling system to control a temperature of the plurality of capacitors below a predetermined temperature threshold.

12. The method of claim 11, wherein:
the predetermined temperature threshold is 35 degrees; and
the plurality of capacitors is implemented as a plurality of supercapacitors connected in series.

13. The method of claim 12, wherein:
the power conversion system further comprises a plurality of electrolytic capacitors coupled to the intermediate voltage bus, and a plurality of batteries coupled to the intermediate voltage bus.

14. The method of claim 13, further comprising:
providing a bidirectional power converter having first input/output terminals connected to the intermediate voltage bus and second input/output terminals connected to the plurality of supercapacitors, the plurality of electrolytic capacitors and the plurality of batteries; and
configuring the bidirectional power converter to manage energy flow between the intermediate voltage bus and the plurality of electrolytic capacitors, the plurality of supercapacitors, and the plurality of batteries, wherein:
the plurality of electrolytic capacitors is configured to provide immediate voltage stabilization by mitigating rapid voltage fluctuations during short duration interruptions;
the plurality of supercapacitors is configured to address medium-duration power deficits by leveraging their high power density and rapid charge-discharge capabilities; and
the plurality of batteries is configured to deliver sustained energy support for extended hold-up times, ensuring continuous system operation during prolonged power interruptions.

15. A system comprising:
a plurality of power factor correction converters connected between an ac power source and an intermediate voltage bus;
a plurality of power converters connected between the intermediate voltage bus and an output voltage bus; and
a plurality of electrolytic capacitors and a plurality of supercapacitors coupled to at least one of respective inputs of the plurality of power factor correction converters, the intermediate voltage bus and the output voltage bus, wherein the plurality of electrolytic capacitors and the plurality of supercapacitors form a hybrid energy charge/discharge apparatus configured to buffer power variations in the system.

16. The system of claim 15, wherein:
the plurality of electrolytic capacitors and the plurality of supercapacitors are connected to the intermediate voltage bus.

17. The system of claim 15, wherein:
the plurality of electrolytic capacitors is connected to the intermediate voltage bus through a first controllable switch; and
the plurality of supercapacitors is connected to the intermediate voltage bus through a second controllable switch, and wherein the first controllable switch and the second controllable switch are selectively controlled based on a duration of a power variation such that:
when the duration of the power variation is shorter than a predetermined time threshold, the first controllable switch is turned on while the second controllable switch is turned off; and
when the duration of the power variation is greater than or equal to the predetermined time threshold, both the first controllable switch and the second controllable switch are turned on.

18. The system of claim 17, wherein:
the predetermined time threshold is about one second.

19. The system of claim 15, wherein:
the plurality of electrolytic capacitors is connected to the respective inputs of the plurality of power factor correction converters through a first controllable switch; and
the plurality of supercapacitors is connected to the respective inputs of the plurality of power factor correction converters through a second controllable switch, and wherein the first controllable switch and the second controllable switch are selectively controlled based on a duration of a power variation such that:
when the duration of the power variation is shorter than a predetermined time threshold, the first controllable switch is turned on while the second controllable switch is turned off; and
when the duration of the power variation is greater than or equal to the predetermined time threshold, both the first controllable switch and the second controllable switch are turned on.

20. The system of claim 15, wherein:
the plurality of electrolytic capacitors is connected to the output voltage bus through a first controllable switch; and
the plurality of supercapacitors is connected to the output voltage bus through a second controllable switch, and wherein the first controllable switch and the second controllable switch are selectively controlled based on a duration of a power variation such that:
when the duration of the power variation is shorter than a predetermined time threshold, the first controllable switch is turned on while the second controllable switch is turned off; and
when the duration of the power variation is greater than or equal to the predetermined time threshold, both the first controllable switch and the second controllable switch are turned on.
